(19) United States
(12) Patent Application Publication
(10) Pub. No.: US 2024/0423077 A1
(43) Pub. Date: Dec. 19, 2024

(54) DISPLAY DEVICE

(71) Applicant: Samsung Display Co., LTD., Yongin-si (KR)

(72) Inventor: JOO-NYUNG JANG, Yongin-si (KR)

(21) Appl. No.: 18/680,795

(22) Filed: May 31, 2024

(30) Foreign Application Priority Data
Jun. 15, 2023 (KR) 10-2023-0076670

(51) Int. Cl. H10K 59/80; H10K 59/131; H10K 59/90

(52) U.S. Cl. CPC H10K 59/8794; H10K 59/131; H10K 59/90

(57) ABSTRACT

A display device includes a display panel, a circuit board disposed on the display panel and including a plurality of bump electrodes, and a conductive adhesive member that electrically connects the display panel and the circuit board. The display panel includes a base layer, a plurality of pads arranged on the base layer and spaced apart from each other in a first direction, and a heat absorbing layer disposed between the base layer and the pads, and the heat absorbing layer overlaps the pads in a plan view.

This application claims priority to Korean Patent Application No. 10-2023-0076670, filed on Jun. 15, 2023, and all the benefits accruing therefrom under 35 U.S.C. § 119, the content of which in its entirety is herein incorporated by reference.

### BACKGROUND

### 1. Field

Embodiments of the disclosure described herein relate to a display device.

### 2. Description of the Related Art

Display devices such as televisions, monitors, smart phones, and tablet personal computers (“PCs”) that provide images to users include display panels that display images. Various display panels such as liquid crystal display panels, organic light-emitting display panels, electro wetting display panels, and electrophoretic display panels have been developed as the display panels.

With the recent technological development of a display device, the display device including a flexible display panel is being developed. The display panel includes a plurality of pixels that display an image and a driving circuit for driving the pixels. To thin the display device, the pixels may be arranged on a display area of the display panel, and a circuit board on which driving circuits are mounted may be connected to a non-display area of the display panel.

### SUMMARY

Embodiments of the disclosure provide a display device having improved bonding reliability.

In an embodiment, a display device includes a display panel, a circuit board disposed on the display panel and including a plurality of bump electrodes, and a conductive adhesive member that electrically connects the display panel and the circuit board. The display panel includes a base layer, a plurality of pads arranged on the base layer and spaced apart from each other in a first direction, and a heat absorbing layer disposed between the base layer and the pads, and the heat absorbing layer overlaps the pads in a plan view.

In an embodiment, a display device includes a display panel including a plurality of pad areas and a plurality of non-pad areas arranged alternately with the pad areas in a first direction, a circuit board disposed on the display panel and including a plurality of bump electrodes, and a conductive adhesive member that electrically connects the display panel and the circuit board. The display panel includes a heat absorbing layer overlapping the pad areas and the non-pad areas.

### BRIEF DESCRIPTION OF THE DRAWINGS

The above and other embodiments, advantages and features of the disclosure will become apparent by describing in detail embodiments thereof with reference to the accompanying drawings.

FIG. 1 is a perspective view of an embodiment of a display device according to an embodiment of the disclosure.

FIGS. 2A and 2B are exploded perspective views of the display device according to an embodiment of the disclosure.

FIG. 3 is a cross-sectional view of a display module illustrated in FIG. 2A.

FIG. 4 is a plan view of a display panel illustrated in FIG. 3.

FIG. 5 is a cross-sectional view of one pixel illustrated in FIG. 4.

FIG. 6 is a perspective view of the display panel illustrated in FIG. 4.

FIG. 7 is a cross-sectional view along line I-I′ illustrated in FIG. 6.

FIG. 8 is a cross-sectional view along line II-II′ illustrated in FIG. 6.

FIGS. 9A to 9C are views for describing another embodiment of the disclosure.

FIG. 10 is a view for describing another embodiment of the disclosure.

FIG. 11 is a view for describing another embodiment of the disclosure.

### DETAILED DESCRIPTION

Advantages and features of the disclosure and a method of achieving the advantages and the features will become apparent with reference to an embodiment described below in detail in conjunction with the accompanying drawings. However, the disclosure is not limited to the embodiments described below but will be implemented in various forms, and the illustrated embodiments merely make the disclosure of the disclosure complete, are provided to completely inform the scope of the disclosure to those skilled in the art to which the disclosure belongs, and are merely defined by the scope of the appended claims. Throughout the specification, the same reference numerals refer to the same components.

When it is mentioned that a first element or layer is disposed “on” or “above” a second element or layer, this includes both a case in which the first element or layer is directly on or above the second element or layer and a case in which a third element or layer is interposed therebetween. On other hand, when it is mentioned that the first element is disposed directly “on” or “above” the second element, this indicates that the third element or layer is not interposed therebetween. The term “and/or” includes each of mentioned items and all combinations of one or more of the mentioned items.

Spatially relative terms such as “below”, “beneath”, “lower”, “above”, and “upper” may be used to easily describe a correlation between a first element or component and a second element or component as illustrated in the drawings. The spatially relative terms should be understood as terms including different directions of elements during use or operation in addition to directions illustrated in the drawings. Throughout the specification, the same reference numerals refer to the same components.

Although first, second, and the like are used to describe various elements, various components, and/or various sections, it is apparent that these elements, these components and/or these sections are not limited by these terms. These terms are only used to distinguish one element, one component, or one section from another element, another component, or another section. Thus, it is apparent that a first element, a first component, or a first section mentioned below may be a second element, a second component, or a second section within the technical spirit of the disclosure.

Embodiments described herein will be described with reference to a plan view and a cross-sectional view that are ideal schematic views of the disclosure. Thus, a shape of an illustrative drawing may be modified due to a manufacturing technology and/or a tolerance. Thus, the embodiments of the disclosure are not limited to specific illustrated shapes but also include changes of shapes generated according to a manufacturing process. Thus, the areas illustrated in the drawings have schematic properties, and the shapes of the areas illustrated in the drawings are intended to illustrate specific shapes of areas of elements and not to limit the scope of the disclosure.

Hereinafter, an embodiment of the disclosure will be described in more detail with reference to the accompanying drawings.

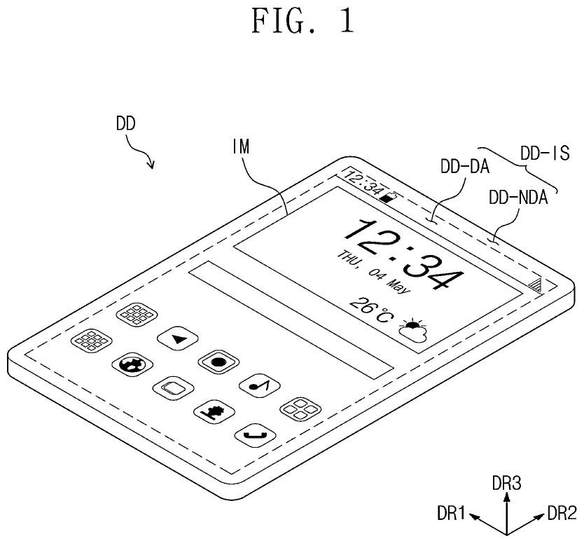

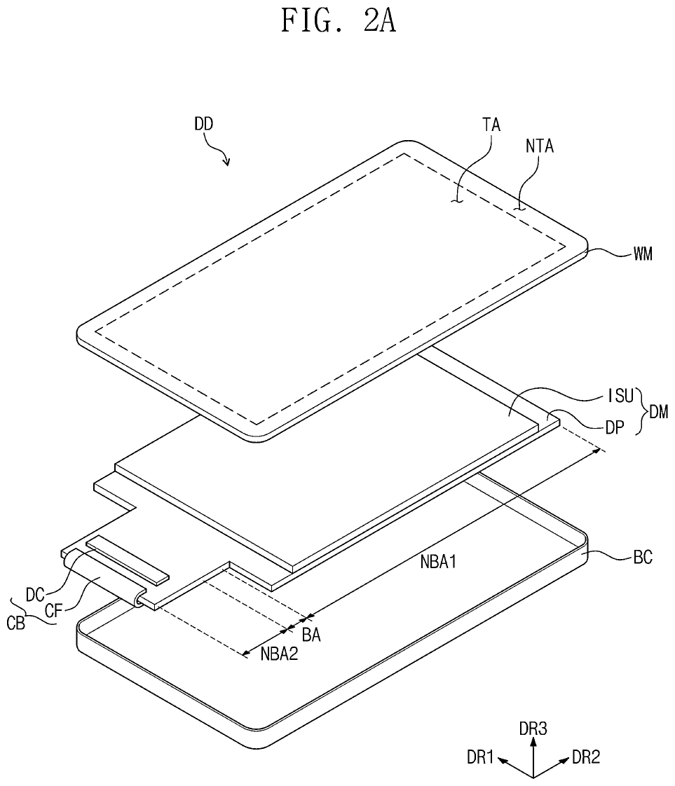

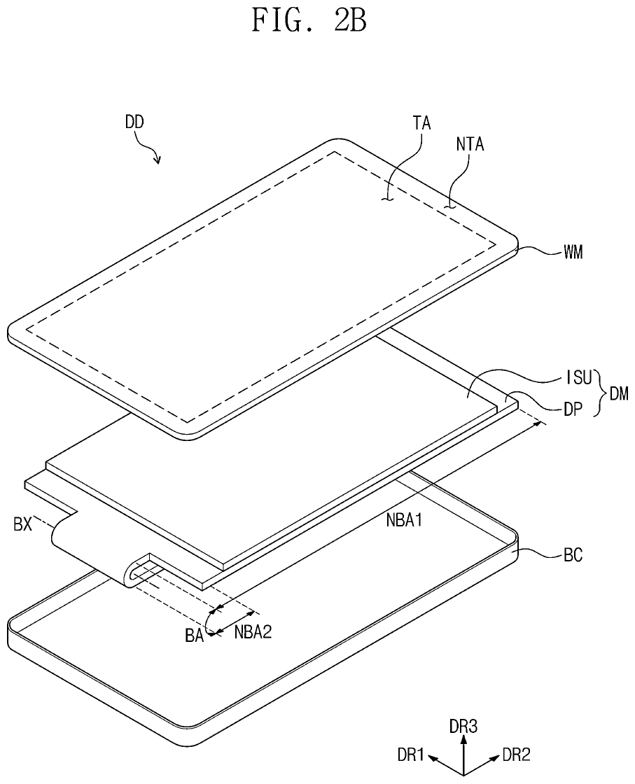

FIG. 1 is a perspective view of an embodiment of a display device according to an embodiment of the disclosure. FIGS. 2A and 2B are exploded perspective views of an embodiment of the display device according to an embodiment of the disclosure.

FIG. 2B illustrates an embodiment of a state in which a bending area BA illustrated in FIG. 2A is bent.

Referring to FIG. 1, in the specification, a display device DD of a mobile phone terminal is illustrated as an example. The display device DD according to the disclosure may be applied to small and medium-sized electronic devices such as tablets, vehicle navigation systems, game consoles, and smart watches as well as large-sized electronic devices such as televisions and monitors.

The display device DD may have a quadrangular shape, e.g., rectangular shape having short sides extending in a first direction DR1 and long sides extending in a second direction DR2 intersecting the first direction DR1 in a plan view. However, the disclosure is not limited thereto, and the display device DD may have various shapes such as a circle and a polygon in a plan view.

Hereinafter, a direction substantially perpendicular to a plane defined by the first direction DR1 and the second direction DR2 is defined as a third direction DR3. In the specification, the wording “in a plan view” means a view in the third direction DR3.

The display device DD may be rigid or flexible. The wording “flexible” may mean a property that may be bent and include both a structure that is completely folded and a structure that may be bent by several nanometers. In an embodiment, the flexible display device DD may include a curved electronic device, a rollable electronic device, and a foldable display device, for example.

The display device DD may display an image IM through a display surface DD-IS. Icon images are illustrated as an example of the image IM. The display surface DD-IS may be parallel to a plane defined by the first direction DR1 and the second direction DR2.

The display surface DD-IS may include a display area DD-DA that displays the image IM and a non-display area DD-NDA adjacent to the display area DD-DA. The non-display area DD-NDA may be an area that does not display an image. However, the disclosure is not limited thereto, and the non-display area DD-NDA may be adjacent to one side of the display area DD-DA or may be omitted.

Referring to FIGS. 2A and 2B, the display device DD may include a window WM, a display module DM, and a storage member BC.

The window WM may be disposed on the display module DM and transmit an image provided from the display module DM to the outside. The window WM may include a transmissive area TA and a non-transmissive area NTA. The transmissive area TA may overlap the display area DD-DA illustrated in FIG. 1 and have a shape corresponding to the display area DD-DA. Although not illustrated, the window WM may include a base layer and functional layers arranged on the base layer. The functional layers may include a protective layer, an anti-fingerprint layer, or the like. The base layer of the window WM may include or consist of glass, sapphire, or plastic. The base layer of the window WM may include an optically transparent insulating material. In an embodiment, the base layer of the window WM may include a glass or plastic film or may include a glass substrate and a plastic film bonded by an adhesive, for example.

The non-transmissive area NTA may overlap the non-display area DD-NDA illustrated in FIG. 1 and have a shape corresponding to the non-display area DD-NDA. The non-transmissive area NTA may be an area having relatively low light transmittance compared to that of the transmissive area TA. The non-transmissive area NTA may be defined by a bezel pattern in a partial area of the base layer of the window WM, and an area in which the bezel pattern is not disposed may be defined as the transmissive area TA. However, the disclosure is not limited thereto, and the non-transmissive area NTA may be omitted.

Although not illustrated, an anti-reflection layer may be disposed between the window WM and the display module DM. The anti-reflection layer may reduce reflectance of an external light beam input from the outside of the display device DD. The anti-reflection layer may include color filters. The color filters may have a predetermined arrangement. In an embodiment, the color filters may be arranged in consideration of light-emitting colors of pixels included in a display panel DP, which will be described below, for example. Further, the anti-reflection layer may further include a black matrix adjacent to the color filters.

According to an embodiment of the disclosure, the display module DM may include the display panel DP and an input sensor ISU.

The display panel DP may be one of a liquid crystal display panel, an electrophoretic display panel, a microelectromechanical system display panel, an electrowetting display panel, an organic light-emitting display panel, an inorganic light-emitting display panel, and a quantum dot light-emitting display panel. However, the disclosure is not particularly limited thereto. Hereinafter, the display panel DP will be described as the organic light-emitting display panel.

The input sensor ISU may include any one of a capacitive sensor, an optical sensor, an ultrasonic sensor, and an electromagnetic induction sensor. The input sensor ISU may be formed on the display panel DP through a subsequent process or may be separately manufactured and then attached to an upper side of the display panel DP through an adhesive layer, and the disclosure is not limited to a particular embodiment.

The display module DM may include a circuit board CB. The circuit board CB may include a driving chip DC and a printed circuit board CF. FIG. 2A illustrates an embodiment in which the driving chip DC is disposed (e.g., mounted) on the display panel DP, but the disclosure is not limited thereto. The driving chip DC may generate a driving signal desired for operation of the display panel DP based on a control signal transmitted from the printed circuit board CF.

The display panel DP may include the bending area BA and a first non-bending area NBA1 and a second non-bending area NBA2 spaced apart from each other in the second direction DR2 with the bending area BA interposed therebetween.

The bending area BA may be defined as an area in which the display panel DP is bent along a virtual bending axis BX extending in the first direction DR1. The first non-bending area NBA1 may be defined as an area overlapping the transmissive area TA, and the second non-bending area NBA2 may be defined as an area to which the printed circuit board CF is connected. When the bending area BA is bent with respect to the virtual bending axis BX, the printed circuit board CF and the driving chip DC may be bent in a direction toward a rear surface of the display panel DP and arranged under the rear surface of the display panel DP. Although not illustrated, additional components may be arranged to compensate for a step difference between the circuit board CB and the rear surface of the display panel DP, which is caused by the bending area BA.

According to an embodiment, a width of the first non-bending area NBA1 in the first direction DR1 may be greater than widths of the bending area BA and the second non-bending area NBA2. However, the disclosure is not limited thereto. The width of the bending area BA in the first direction DR1 may be provided in a shape that becomes narrower from the first non-bending area NBA1 to the second non-bending area NBA2. The disclosure is not limited to a particular embodiment.

As illustrated in FIG. 2B, as a portion of the display panel DP is bent, the printed circuit board CF electrically bonded to the display panel DP may be disposed on the rear surface of the display panel DP.

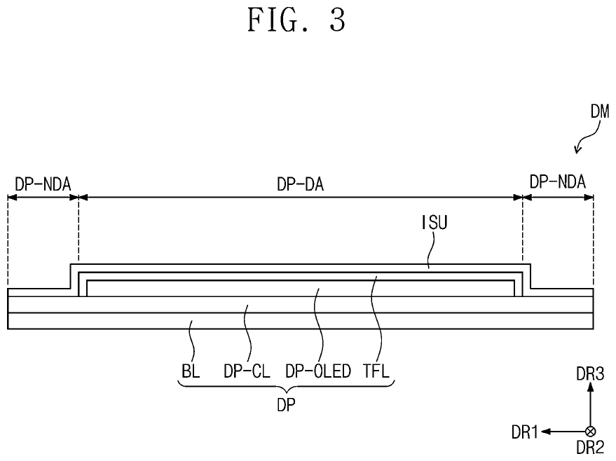

The storage member BC may accommodate the display module DM and may be coupled to the window WM. The printed circuit board CF may be disposed at one end of the display panel DP and may be electrically connected to a circuit element layer DP-CL, which will be described in FIG. 3. Although not illustrated, the display device DD may further include a main board, electronic modules disposed (e.g., mounted) on the main board, a camera module, a power module, or the like.

Hereinabove, an example of the display device DD has been described as the mobile phone terminal, but in the specification, the display device DD may include two or more electrically bonded electronic components. The display panel DP and the driving chip DC disposed (e.g., mounted) on the display panel DP may correspond to different electronic components, only the display panel DP and the driving chip DC may constitute the display device DD, and the disclosure is not limited to a particular embodiment.

In an embodiment, only the display panel DP and the printed circuit board CF connected to the display panel DP may constitute the display device DD, and only the main board and the electronic module disposed (e.g., mounted) on the main board may constitute the display device DD. Hereinafter, the display device DD according to the disclosure will be described while focusing on a bonding structure of the display panel DP and the driving chip DC disposed (e.g., mounted) on the display panel DP.

FIG. 3 is a cross-sectional view of a display module illustrated in FIG. 2A.

Referring to FIG. 3, the display panel DP may include a base layer BL, the circuit element layer DP-CL disposed on the base layer BL, a display element layer DP-OLED, and an upper insulating layer TFL. The input sensor ISU may be disposed on the upper insulating layer TFL.

The display panel DP may include a display area DP-DA and a non-display area DP-NDA. The display area DP-DA of the display panel DP may correspond to the display area DD-DA illustrated in FIG. 1 or the transmissive area TA illustrated in FIG. 2A, and the non-display area DP-NDA may correspond to the non-display area DD-NDA illustrated in FIG. 1 or the non-transmissive area NTA illustrated in FIG. 2A.

The base layer BL may include at least one plastic film. The base layer BL is a flexible substrate and may include a plastic substrate, a glass substrate, a metal substrate, or an organic/inorganic composite material substrate.

The circuit element layer DP-CL may include at least one intermediate insulating layer and at least one circuit element. The intermediate insulating layer may include at least one intermediate inorganic layer and at least one intermediate organic layer. The circuit element may include signal lines, a driving circuit of a pixel, or the like.

The display element layer DP-OLED may include a plurality of organic light-emitting diodes. The display element layer DP-OLED may further include an organic layer such as a pixel definition film.

The upper insulating layer TFL may seal the display element layer DP-OLED. The upper insulating layer TFL may be disposed on the display element layer DP-OLED. The upper insulating layer TFL may overlap the display area DP-DA and the non-display area DP-NDA. The upper insulating layer TFL may overlap at least a portion of the non-display area DP-NDA. In an embodiment, the upper insulating layer TFL may include a thin film encapsulation layer, for example. The thin film encapsulation layer may include a laminated structure of an inorganic layer, an organic layer, and an inorganic layer. The upper insulating layer TFL may protect the display element layer DP-OLED from foreign substances such as moisture, oxygen, and dust particles. However, the disclosure is not limited thereto, and the upper insulating layer TFL may further include an additional insulating layer other than the thin film encapsulation layer. In an embodiment, the upper insulating layer TFL may further include an optical insulating layer for controlling a refractive index, for example.

In an embodiment of the disclosure, an encapsulation substrate may be provided instead of the upper insulating layer TFL. In this case, the encapsulation substrate faces the base layer BL, and the circuit element layer DP-CL and the display element layer DP-OLED may be arranged between the encapsulation substrate and the substrate.

The input sensor ISU may be directly disposed on the display panel DP. In the specification, the wording “component A is directly disposed on component B” means that no separate layer is disposed between component A and component B. In an embodiment, the input sensor ISU may be manufactured by a continuous process together with the display panel DP. However, the technical idea of the disclosure is not limited thereto, and the input sensor ISU may be provided as an individual panel and coupled to the display panel DP through an adhesive layer. As an example, the input sensor ISU may be omitted.

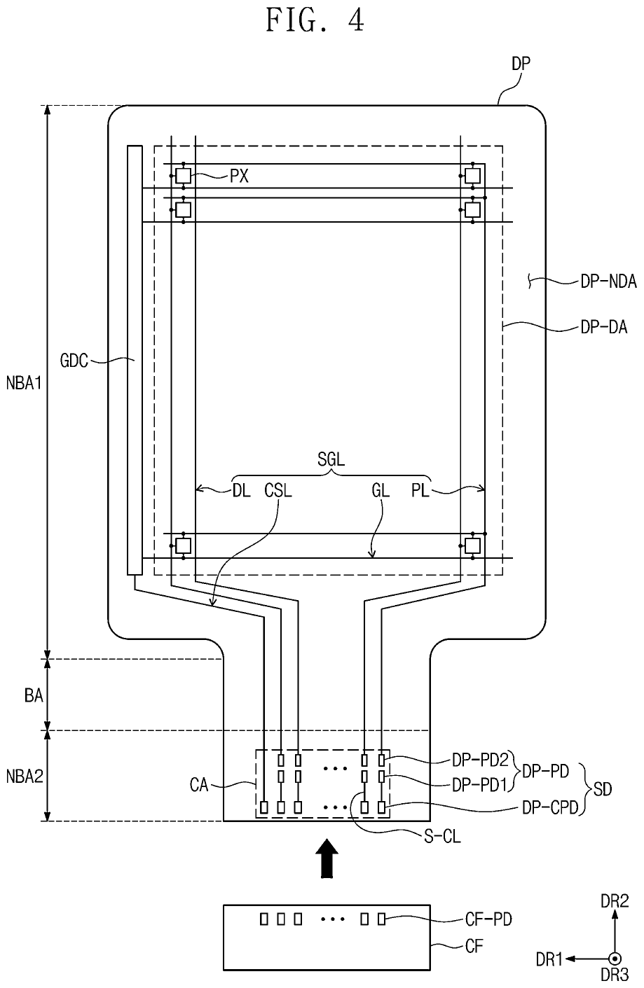

FIG. 4 is a plan view of a display panel illustrated in FIG. 3.

Referring to FIG. 4, the display panel DP may include a plurality of pixels PX, a gate driving circuit GDC, a plurality of signal lines SGL, and a plurality of display pads SD.

The pixels PX may be arranged in the display area DP-DA. Each of the pixels PX may include an organic light-emitting diode and a pixel driving circuit connected thereto. The gate driving circuit GDC and the signal lines SGL may be included in the circuit element layer DP-CL illustrated in FIG. 3.

The gate driving circuit GDC may sequentially output gate signals to a plurality of gate lines GL. The gate driving circuit GDC may include a plurality of thin film transistors formed through the same process as that of the driving circuits of the pixels PX, e.g., a low temperature polycrystaline silicon (“LTPS”) process or a low temperature polycrystalline oxide (“LTPO”) process. The display panel DP may further include another driving circuit that provides light-emitting control signals to the pixels PX.

The signal lines SGL may include the gate lines GL, data lines DL, a power line PL, and a control signal line CSL. Each of the gate lines GL may extend in the first direction DR1 and may be connected to a corresponding pixel PX among the pixels PX, and each of the data lines DL may extend in the second direction DR2 and may be connected to a corresponding pixel PX among the pixels PX. The power line PL may extend in the first direction DR1 and the second direction DR2 and may be connected to the pixels PX. The control signal lines CSL may provide control signals to a scan driving circuit.

The signal lines SGL may overlap the display area DP-DA and the non-display area DP-NDA. Each of the signal lines SGL may include a pad part and a line part. The line part may overlap the display area DP-DA and the non-display area DP-NDA. The pad part may be connected to a distal end of the line part. The pad part may overlap a pad area, which will be described below.

The display panel DP may include the plurality of display pads SD. The plurality of display pads SD may be spaced apart from each other with a predetermined distance. The plurality of display pads SD according to an embodiment may be arranged in a connection area CA of the second non-bending area NBA2. The connection area CA may be defined as an area of the second non-bending area NBA2, in which the display pads SD are arranged. The driving chip DC (refer to FIG. 2A) and the printed circuit board CF (refer to FIG. 2A) may be attached to the connection area CA.

The display pads SD may include first pads DP-PD and second pads DP-CPD. The first pads DP-PD may be arranged to overlap the connection area CA. The driving chip DC (refer to FIG. 2A) may be disposed (e.g., mounted) on the second non-bending area NBA2. The first pads DP-PD may be electrically connected to the driving chip DC to transmit electrical signals received from the driving chip DC to the signal lines SGL.

The first pads DP-PD may be arranged in the first direction DR1 and the second direction DR2. The first pads DP-PD may include first row pads DP-PD1 and second row pads DP-PD2 spaced apart from the first row pads DP-PD1 in the second direction DR2 and arranged in the first direction DR1. The second row pads DP-PD2 may be input pads that receive signals from the driving chip DC, and the first row pads DP-PD1 may be output pads that output signals to the driving chip DC.

However, the disclosure is not limited thereto, and the first pads DP-PD may be arranged in one row or in three or more rows in the second direction DR2.

The second pads DP-CPD may be arranged to overlap the connection area CA. The first pads DP-PD and the second pads DP-CPD may be connected to each other through bridge signal lines S-CL.

Like the first pads DP-PD, the second pads DP-CPD may also be arranged in the first direction DR1. The second pads DP-CPD may be arranged to be spaced apart from each other in the first direction DR1.

The printed circuit board CF may include substrate bump electrodes CF-PD electrically connected to the display panel DP. An arrangement of the substrate bump electrodes CF-PD included in the printed circuit board CF may be provided as an arrangement of the second pads DP-CPD. In an embodiment, when the second pads DP-CPD are provided in a form arranged in the first direction DR1, the substrate bump electrodes CF-PD may be arranged in the first direction DR1. However, this is, and the disclosure is not limited thereto.

The second pads DP-CPD may be electrically connected to the substrate bump electrodes CF-PD included in the printed circuit board CF and transmit electrical signals received from the printed circuit board CF to the first pads DP-PD. The printed circuit board CF may be rigid or flexible. In an embodiment, when the printed circuit board CF is flexible, the printed circuit board CF may be provided as a flexible printed circuit board, for example.

Although not illustrated, the printed circuit board CF may include a timing control circuit that controls operation of the display panel DP. The timing control circuit may be disposed (e.g., mounted) on the printed circuit board CF in the form of an integrated chip. Also, although not illustrated, the printed circuit board CF may include an input detection circuit that controls the input sensor ISU shown in FIG. 3.

A structure in which the display panel DP of the disclosure includes the first pads DP-PD for mounting the driving chip DC illustrated in FIG. 2A has been described, but the disclosure is not limited thereto. The driving chip DC may be disposed (e.g., mounted) on the printed circuit board CF, and in this case, the first pads DP-PD may be omitted.

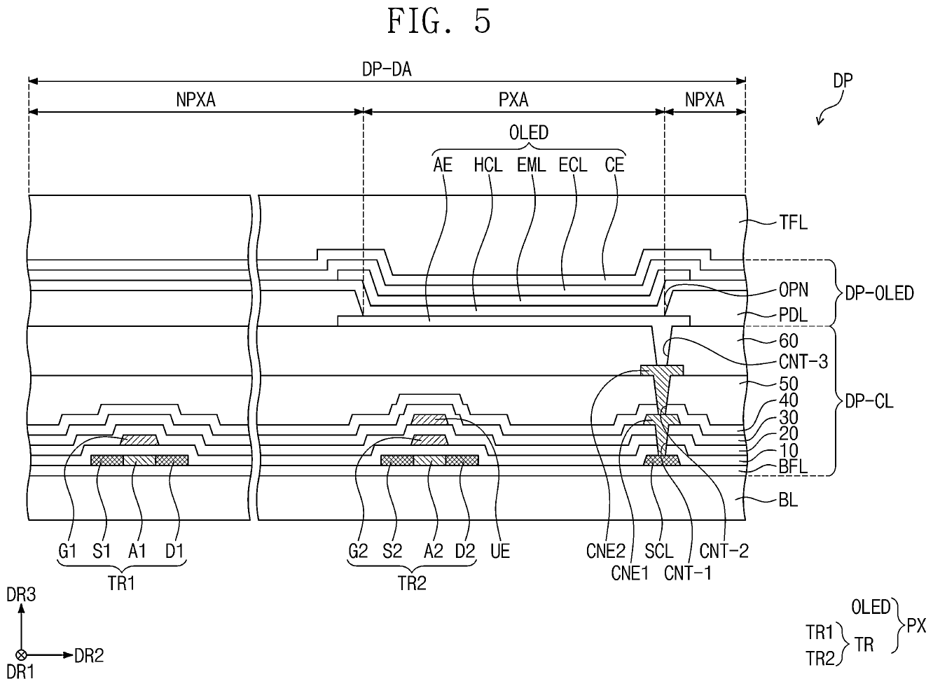

FIG. 5 is a cross-sectional view of one pixel illustrated in FIG. 4.

Referring to FIG. 5, the display area DP-DA may include a light-emitting area PXA and a non-light-emitting area NPXA. Each of the pixels PX may include an organic light-emitting diode (“OLED”) and a pixel driving circuit connected thereto. In detail, the pixel PX may include a first transistor TR1, a second transistor TR2, and the OLED. In an embodiment, the first transistor TR1 and the second transistor TR2 may be collectively referred to as a transistor TR.

FIG. 5 illustrates an embodiment of the two transistors TR1 and TR2, but the disclosure is not limited thereto. The pixel PX may include seven transistors and at least one capacitor, and the seven transistors and the capacitor are electrically connected to each other.

The display panel DP may include a plurality of insulating layers, a semiconductor pattern, a conductive pattern, a signal line, or the like. The insulating layer, a semiconductor layer, and a conductive layer are formed by coating, deposition, or the like. Thereafter, the insulating layer, the semiconductor layer, and the conductive layer may be selectively patterned by photolithography. In this manner, the semiconductor pattern, the conductive pattern, the signal line, or the like included in the circuit element layer DP-CL and the display element layer DP-OLED are formed.

The base layer BL may include a synthetic resin film. The base layer BL may have a multi-layered structure. In an embodiment, the base layer BL may have a three-layer structure of a synthetic resin layer, an inorganic layer, and a synthetic resin layer, for example. In particular, the synthetic resin layer may be a polyimide-based resin layer, for example, and a material thereof is not particularly limited thereto. In addition, the base layer BL may include a glass substrate, a metal substrate, an organic/inorganic composite material substrate, or the like.

At least one inorganic layer is disposed on an upper surface of the base layer BL. The inorganic layer may be formed in multiple layers. The multi-layered inorganic layers may constitute a barrier layer and/or a buffer layer. In an embodiment, it is illustrated that the display panel DP includes a buffer layer BFL.

The semiconductor pattern is disposed on the buffer layer BFL. The semiconductor pattern may include polysilicon. However, the disclosure is not limited thereto, and the semiconductor pattern may include amorphous silicon or metal oxide.

FIG. 5 merely illustrates a portion of the semiconductor pattern, and the semiconductor pattern may be further disposed in another area of the pixel PX in a plan view. The semiconductor pattern may be disposed in a predetermined rule across the pixels. The semiconductor pattern has different electrical properties depending on whether the semiconductor pattern is doped. The semiconductor pattern may include a first area and a second area. The first area may be doped with an N-type dopant or a P-type dopant. A P-type transistor includes a doped area doped with the P-type dopant.

A conductivity of the first area is greater than a conductivity of the second area, and the first area substantially serves as an electrode or a signal line. The second area has a relatively low doping concentration or may be a non-doped area, and substantially corresponds to an active area (or a channel area) of the transistor. In other words, a portion of the semiconductor pattern may be an active area of a transistor, another portion of the semiconductor pattern may be a source area or a drain area of the transistor, and still another portion of the semiconductor pattern may be a connection electrode or a connection signal line.

As illustrated in FIG. 5, a first source area S1, a first active area A1, and a first drain area D1 of the first transistor TR1 are formed from the semiconductor pattern, and a second source area S2, a second active area A2, and a second drain area D2 of the second transistor TR2 are formed from the semiconductor pattern.

FIG. 5 illustrates a portion of a connection signal line SCL formed from the semiconductor pattern. Although not separately illustrated, the connection signal line SCL may be electrically connected to the second drain area D2 of the second transistor TR2 in a plan view. Another transistor may be disposed between the connection signal line SCL and the second drain area D2 of the second transistor TR2.

A first insulating layer 10 is disposed on the buffer layer BFL. The first insulating layer 10 commonly overlaps the plurality of pixels PX and covers the semiconductor pattern. First and second gates G1 and G2 are arranged on the first insulating layer 10. The first and second gates G1 and G2 may be portions of a metal pattern. The first gate G1 overlaps the first active area A1, and the second gate G2 overlaps the second active area A2. In a process of doping the semiconductor pattern, the first and second gates G1 and G2 serve as masks.

A second insulating layer 20 that covers the first and second gates G1 and G2 is disposed on the first insulating layer 10. The second insulating layer 20 commonly overlaps the pixels PX. An upper electrode UE may be disposed on the second insulating layer 20. The upper electrode UE may overlap the second gate G2 of the second transistor TR2. The upper electrode UE may be a portion of the metal pattern. A portion of the second gate G2 and the upper electrode UE overlapping the portion of the second gate G2 may define a capacitor.

A third insulating layer 30 that covers the upper electrode UE is disposed on the second insulating layer 20. A first connection electrode CNE1 disposed on the third insulating layer 30 may be connected to the connection signal line SCL through a contact hole CNT-1 passing through the first to third insulating layers 10 to 30.

A fourth insulating layer 40 that covers the first connection electrode CNE1 is disposed on the third insulating layer 30. The first insulating layer 10 to the fourth insulating layer 40 may be an inorganic layer and/or an organic layer and may have a single-layer or multi-layer structure.

A fifth insulating layer 50 is disposed on the fourth insulating layer 40. The fifth insulating layer 50 may be an organic layer. A second connection electrode CNE2 may be disposed on the fifth insulating layer 50. The second connection electrode CNE2 may be connected to the first connection electrode CNE1 through a contact hole CNT-2 passing through the fourth insulating layer 40 and the fifth insulating layer 50.

A sixth insulating layer 60 that covers the second connection electrode CNE2 is disposed on the fifth insulating layer 50. The sixth insulating layer 60 may be an organic layer. A first electrode AE is disposed on the sixth insulating layer 60. The first electrode AE is connected to the second connection electrode CNE2 through a contact hole CNT-3 passing through the sixth insulating layer 60.

A pixel opening OPN is defined in a pixel definition film PDL. The pixel opening OPN of the pixel definition film PDL exposes at least a portion of the first electrode AE. In an embodiment, the light-emitting area PXA is defined to correspond to a partial area of the first electrode AE, which is exposed by the pixel opening OPN.

A hole control layer HCL may be commonly disposed in the light-emitting area PXA and the non-light-emitting area NPXA. The hole control layer HCL may include a hole transport layer and may further include a hole injection layer. A light-emitting layer EML is disposed on the hole control layer HCL. The light-emitting layer EML may be disposed in an area corresponding to the pixel opening OPN. That is, the light-emitting layers EML may be separately formed in each pixel. However, the disclosure is not limited thereto, and the light-emitting layer EML may be commonly formed in the plurality of pixels PX using an open mask.

An electron control layer ECL is disposed on the light-emitting layer EML. The electron control layer ECL may include an electron transport layer and may further include an electron injection layer. The hole control layer HCL and the electron control layer ECL may be commonly formed in the plurality of pixels using an open mask. A second electrode CE is disposed on the electron control layer ECL. The second electrode CE has an integral shape and is commonly disposed in the plurality of pixels PX. The upper insulating layer TFL is disposed on the second electrode CE. The upper insulating layer TFL may include a plurality of thin films.

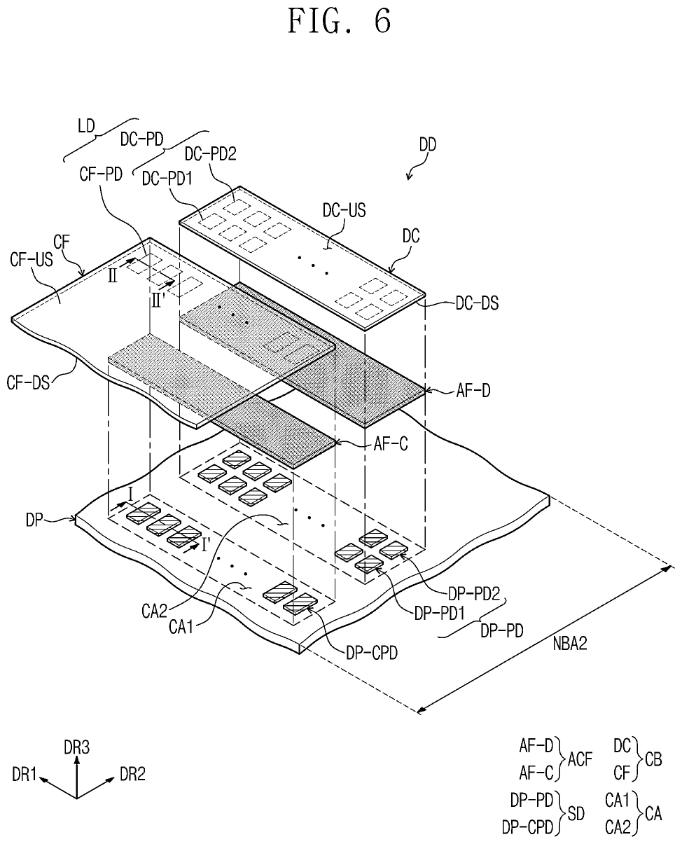

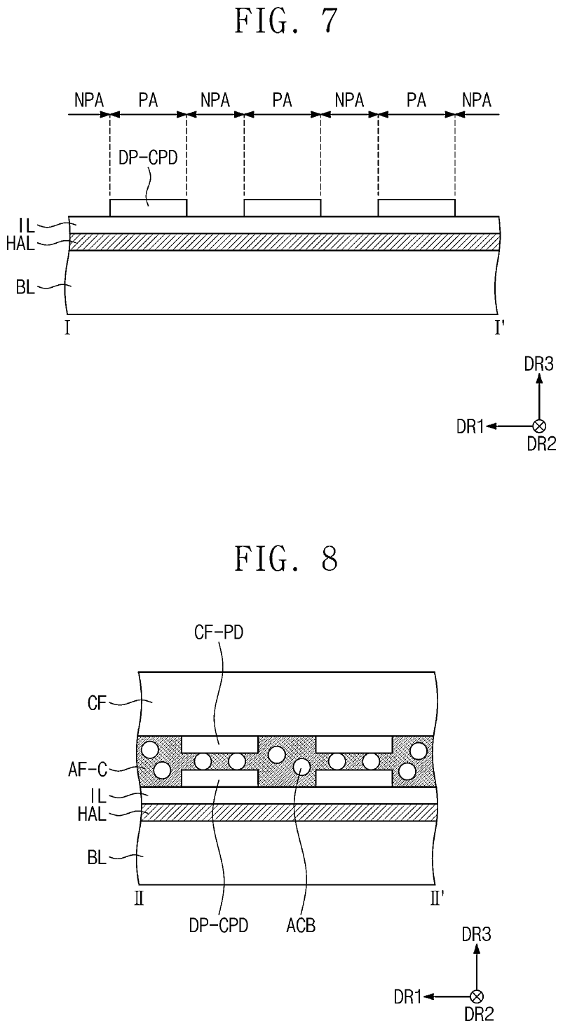

FIG. 6 is a perspective view of the display panel illustrated in FIG. 4. FIG. 7 is a cross-sectional view along line I-I′ illustrated in FIG. 6. FIG. 8 is a cross-sectional view along line II-II′ illustrated in FIG. 6.

FIG. 6 is a view illustrating an embodiment of a partial area of the second non-bending area NBA2.

FIG. 6 is a schematic view illustrating an embodiment of some components arranged to correspond to the second non-bending area NBA2.

Since the second pads DP-CPD and the base layer BL of FIG. 7 are the same as the second pads DP-CPD of FIG. 4 and the base layer BL of the FIG. 5, a duplicated description thereof will be omitted or simplified.

FIGS. 7 and 8 illustrate an embodiment of the second pads DP-CPD and the base layer BL, a heat absorbing layer HAL, and an insulating layer IL overlapping the second pads DP-CPD, but the base layer BL, the heat absorbing layer HAL, and the insulating layer IL overlapping the first pads DP-PD may also have the same configuration.

For convenience of description, in FIGS. 7 and 8, the second pads DP-CPD, the display panel DP overlapping the second pads DP-CPD, and the substrate bump electrodes CF-PD are mainly described. However, the disclosure is not limited thereto, and the first pads DP-PD, the display panel DP overlapping the first pads DP-PD, and chip bump electrodes DC-PD may have substantially the same configuration.

Referring to FIGS. 6 to 8, the display device DD may include the circuit board CB, a conductive adhesive member ACF, and the display panel DP. In FIG. 6, for convenience of description, the display panel DP, the conductive adhesive member ACF, and the circuit board CB are disassembled and spaced apart from each other. However, as illustrated in FIG. 8, the display panel DP, the conductive adhesive member ACF, and the circuit board CB may be coupled to each other. That is, at least a portion of the display panel DP may contact the conductive adhesive member ACF, and at least a portion of the circuit board CB may contact the conductive adhesive member ACF.

An area of the second non-bending area NBA2, in which the printed circuit board CF is bonded may be defined as a first connection area CA1, and an area thereof, in which the driving chip DC is bonded, may be defined as a second connection area CA2.

The circuit board CB may include a plurality of bump electrodes LD. The plurality of bump electrodes LD may include the substrate bump electrodes CF-PD disposed (e.g., mounted) on the printed circuit board CF and the chip bump electrodes DC-PD disposed (e.g., mounted) on the driving chip DC.

The printed circuit board CF may include an upper surface CF-US and a lower surface CF-DS. The lower surface CF-DS of the printed circuit board CF may be defined as a surface facing the display panel DP. The substrate bump electrodes CF-PD may be disposed on the lower surface CF-DS of the printed circuit board CF.

The substrate bump electrodes CF-PD may be arranged on the lower surface CF-DS of the printed circuit board CF in the first direction DR1. The substrate bump electrodes CF-PD may be arranged to be spaced apart from each other in the first direction DR1. In a plan view, an arrangement shape of the substrate bump electrodes CF-PD may be the same as an arrangement shape of the second pads DP-CPD arranged on the display panel DP.

As illustrated in FIG. 8, the substrate bump electrodes CF-PD may have a shape exposed to the outside from the lower surface CF-DS of the printed circuit board CF.

The driving chip DC may include an upper surface DC-US and a lower surface DC-DS. The lower surface DC-DS of the driving chip DC may be a surface facing the display panel DP. The chip bump electrodes DC-PD may be disposed on the lower surface DC-DS of the driving chip DC.

The chip bump electrodes DC-PD may be arranged in the first direction DR1 and the second direction DR2. The chip bump electrodes DC-PD may include first row chip bump electrodes DC-PD1 arranged in the first direction DR1 and second row chip bump electrodes DC-PD2 spaced apart from the first row chip bump electrodes DC-PD1 in the second direction DR2 and arranged in the first direction DR1. In a plan view, an arrangement shape of the chip bump electrodes DC-PD may be the same as an arrangement shape of the first pads DP-PD arranged on the display panel DP.

Although not illustrated, the chip bump electrodes DC-PD may have a shape exposed to the outside from the lower surface DC-DS of the driving chip DC.

Referring to FIGS. 7 and 8, the second pads DP-CPD may be arranged on the base layer BL. When viewed in the second direction DR2, the second pads DP-CPD may be spaced apart from each other in the first direction DR1 and arranged in the first direction DR1.

The display panel DP (refer to FIG. 4) may include a plurality of pad areas PA and a plurality of non-pad areas NPA. The pad areas PA may be defined as areas overlapping the second pads DP-CPD. The non-pad areas NPA may be defined as areas between the second pads DP-CPD adjacent to each other in the first direction DR1. When viewed in the second direction DR2, the pad areas PA and the non-pad areas NPA may be alternately arranged in the first direction DR1.

The heat absorbing layer HAL may be disposed on the base layer BL. The heat absorbing layer HAL may be disposed between the base layer BL and the second pads DP-CPD.

When viewed in the second direction DR2, the heat absorbing layer HAL may extend in the first direction DR1. The heat absorbing layer HAL may overlap the pad areas PA and the non-pad areas NPA.

The heat absorbing layer HAL may include metal. In an embodiment, the heat absorbing layer HAL may include any one of molybdenum (Mo), titanium (Ti), or nickel (Ni), but the disclosure is not limited thereto, and the heat absorbing layer HAL may include other metals. Further, the heat absorbing layer HAL may include an inorganic material.

The insulating layer IL may be disposed on the heat absorbing layer HAL. The insulating layer IL may cover the heat absorbing layer HAL. The heat absorbing layer HAL including a metal may be insulated from the second pads DP-CPD by the insulating layer IL. As the insulating layer IL is disposed, the second pads DP-CPD may be prevented from being shorted to each other by the heat absorbing layer HAL including a metal.

The insulating layer IL may be an inorganic layer. In an embodiment, t, the insulating layer IL may include a silicon oxide (SiO_{X}) or a silicon nitride (SiN_{X}), but the disclosure is not limited thereto, and the insulating layer IL may include other inorganic materials.

Referring to FIGS. 6 and 8, the conductive adhesive member ACF may be disposed between the circuit board CB and the display panel DP. The conductive adhesive member ACF may be an anisotropic conductive film. In an embodiment, the conductive adhesive member ACF may include an adhesive resin and conductive balls ACB dispersed in the adhesive resin, for example. In an alternative embodiment, the conductive adhesive member ACF may be a non-conductive film. In an embodiment, the conductive adhesive member ACF may be an adhesive resin that does not include or consist of conductive particles, for example. The conductive adhesive member ACF may include a thermosetting resin.

The conductive adhesive member ACF may include a first conductive adhesive member AF-C disposed between the printed circuit board CF and the display panel DP and a second conductive adhesive member AF-D disposed between the driving chip DC and the display panel DP.

The first conductive adhesive member AF-C may bond the printed circuit board CF to the first connection area CA1 of the display panel DP. The printed circuit board CF may be bonded to the first connection area CA1 by the first conductive adhesive member AF-C. Each of the substrate bump electrodes CF-PD may be electrically connected to a corresponding second pad DP-CPD among the second pads DP-CPD by the first conductive adhesive member AF-C. The substrate bump electrodes CF-PD and the second pads DP-CPD may be electrically connected to each other by the conductive balls ACB. Accordingly, the printed circuit board CF may be electrically connected to the display panel DP.

The second conductive adhesive member AF-D may bond the driving chip DC to the second connection area CA2 of the display panel DP. The driving chip DC may be bonded to the second connection area CA2 by the second conductive adhesive member AF-D. Each of the chip bump electrodes DC-PD may be electrically connected to a corresponding first pad DP-PD among the first pads DP-PD by the second conductive adhesive member AF-D. Although not illustrated, the chip bump electrodes DC-PD and the first pads DP-PD may be electrically connected to each other by the conductive balls ACB. Accordingly, the driving chip DC may be electrically connected to the display panel DP.

Although not illustrated, when the circuit board CB and the display panel DP are arranged adjacent to the conductive adhesive member ACF, a near-infrared laser beam may be irradiated from a lower side of the base layer BL in the third direction DR3. As the near-infrared laser beam is irradiated, the conductive adhesive member ACF may be cured. As the conductive adhesive member ACF is cured, the circuit board CB and the display panel DP may be connected to each other.

When the display panel DP does not include the heat absorbing layer HAL, the near-infrared laser beam may pass through the base layer BL and the conductive adhesive member ACF and may be absorbed by the circuit board CB. The circuit board CB may absorb the near-infrared laser beam and be converted into a high-temperature state. The circuit board CB converted into the high-temperature state may emit heat. The heat emitted from the circuit board CB may move toward the conductive adhesive member ACF, and the conductive adhesive member ACF may be cured. In this case, the circuit board CB may be expanded by the heat. That is, the driving chip DC and the printed circuit board CF may be expanded.

When the driving chip DC and the printed circuit board CF are expanded in the first direction DR1 or the second direction DR2, the positions of the substrate bump electrodes CF-PD and the chip bump electrodes DC-PD may be changed. Accordingly, the positions of the chip bump electrodes DC-PD and the substrate bump electrodes CF-PD may not correspond to the positions of the first pads DP-PD and the second pads DP-CPD on the display panel DP. Thus, bonding failure between the display panel DP and the circuit board CB may occur.

However, when the heat absorbing layer HAL is disposed between the base layer BL and the second pads DP-CPD, the near-infrared laser beam irradiated from the lower side of the base layer BL is absorbed by the heat absorbing layer HAL. The heat absorbing layer HAL that absorbs the near-infrared laser beam may be in a high-temperature state, and the heat absorbing layer HAL may emit the heat to the pad areas PA and the non-pad areas NPA. The heat may be transferred to the conductive adhesive member ACF, and the conductive adhesive member ACF may be cured.

Accordingly, while the conductive adhesive member ACF is cured, the circuit board CB may be prevented from being in a high-temperature state, and thus the circuit board CB may be prevented from being expanded by the heat. As the circuit board CB is not expanded by the heat, the positions of the substrate bump electrodes CF-PD may not be changed. Thus, bonding reliability between the display panel DP and the circuit board CB may be improved.

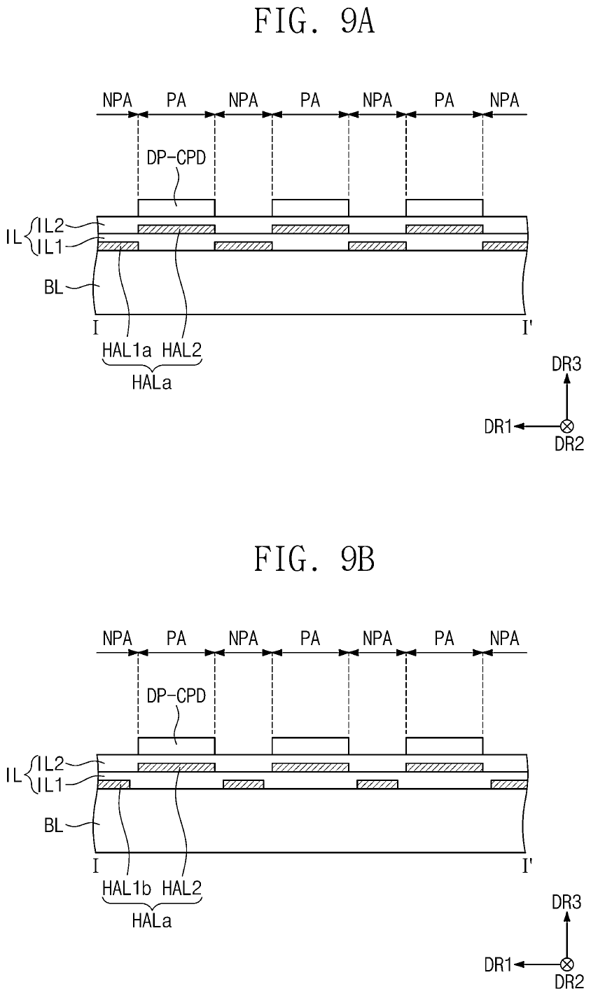

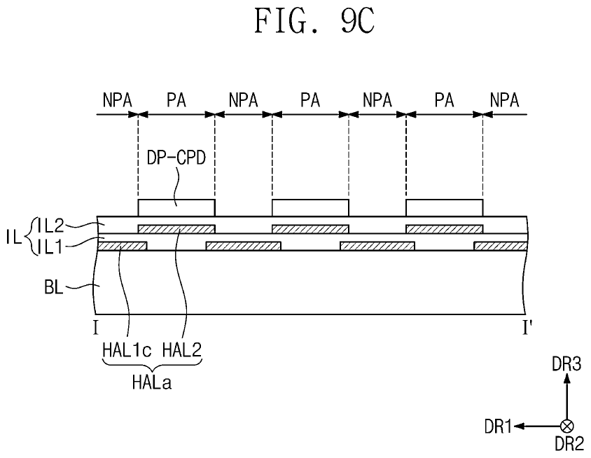

FIGS. 9A to 9C are views for describing another embodiment of the disclosure.

FIGS. 9A to 9C are cross-sectional views of an embodiment.

In an embodiment shown in FIGS. 9A to 9C, except for sizes of first heat absorbing layers HAL1a, HAL1b, and HAL1c in the first direction DR1, which are different from each other, the other configurations may be the same.

Since the base layer BL, the second pads DP-CPD, the pad areas PA, and the non-pad areas NPA of FIGS. 9A to 9C are the same as the base layer BL, the second pads DP-CPD, the pad areas PA, and the non-pad areas NPA of FIG. 7, a description thereof will be omitted or simplified.

Referring to FIGS. 6 and 9A, a heat absorbing layer HALa may include a plurality of (1-1)^{th} heat absorbing layers HAL1a and a plurality of second heat absorbing layers HAL2. Each of the (1-1)^{th} heat absorbing layers HAL1a and the second heat absorbing layers HAL2 may include a metal. In an embodiment, the (1-1)^{th} heat absorbing layers HAL1a and the second heat absorbing layers HAL2 may include any one of titanium (Ti), molybdenum (Mo), and nickel (Ni), but the disclosure is not limited thereto, and the (1-1)^{th} heat absorbing layers HAL1a and the second heat absorbing layers HAL2 may include other metals.

The (1-1)^{th} heat absorbing layers HAL1a may be arranged on the base layer BL. The (1-1)^{th} heat absorbing layers HAL1a may be arranged in the first direction DR1. The (1-1)^{th} heat absorbing layers HAL1a may be spaced apart from each other in the first direction DR1.

A width of the (1-1)^{th} heat absorbing layers HAL1a in the first direction DR1 may be the same as a width of the non-pad areas NPA in the first direction DR1.

A first insulating layer IL1 may be disposed on the base layer BL. The first insulating layer IL1 may be disposed to cover the (1-1)^{th} heat absorbing layers HAL1a arranged on the base layer BL. Accordingly, the (1-1)^{th} heat absorbing layers HAL1a may not be electrically connected to the second heat absorbing layers HAL2.

The first insulating layer IL1 may be an organic layer. In an embodiment, the first insulating layer IL1 may include a silicon oxide (SiO_{X}) or a silicon nitride (SiNₓ), but the disclosure is not limited thereto, and the first insulating layer IL1 may include other inorganic materials.

The second heat absorbing layers HAL2 may be arranged on the first insulating layer IL1. The second heat absorbing layers HAL2 may be arranged in the first direction DR1. The second heat absorbing layers HAL2 may be spaced apart from each other in the first direction DR1. In an embodiment, a second insulating layer IL2 may be disposed on the first insulating layer IL1 and the second heat absorbing layers HAL2.

Referring to FIGS. 9B, when viewed in the second direction DR2, a size of the (1-2)^{th} heat absorbing layers HAL1b in the first direction DR1 may be smaller than a width of the non-pad areas NPA in the first direction DR1. The (1-2)^{th} heat absorbing layers HAL1b may not overlap the pad areas PA. The (1-2)^{th} heat absorbing layers HAL1b may not overlap the second pads DP-CPD.

Referring to FIG. 9C, a width of the (1-3)^{th} heat absorbing layers HAL1c in the first direction DR1 may be greater than the width of the non-pad areas NPA in the first direction DR1. The (1-3)^{th} heat absorbing layers HAL1c may overlap the pad areas PA and the non-pad areas NPA. The (1-3)^{th} heat absorbing layers HAL1c may overlap edges of the second pads DP-CPD. The (1-3)^{th} heat absorbing layers HAL1c may overlap portions of the second heat absorbing layers HAL2.

Referring to FIGS. 9A to 9C, when the near-infrared laser beam is irradiated from the lower side of the base layer BL in the third direction DR3, the first heat absorbing layers HAL1a, HAL1b, and HAL1c that absorb the near-infrared laser beam may emit the heat toward the conductive adhesive member ACF (refer to FIG. 6) overlapping the non-pad areas NPA. The second heat absorbing layers HAL2 that absorb the near-infrared laser beam may emit the heat toward the conductive adhesive member ACF (refer to FIG. 6) overlapping the pad areas PA. Accordingly, the conductive adhesive member ACF may be cured to bond the display panel DP and the circuit board CB.

Further, since the near-infrared laser beam is absorbed by the first heat absorbing layers HAL1a, HAL1b and HAL1c and a second heat absorbing layer HAL2, the quantity of the near-infrared laser beam absorbed by the circuit board CB may be relatively small. Accordingly, the circuit board CB may not be in a high-temperature state caused by the near-infrared laser beam, and the circuit board CB may not be deformed by the heat. That is, positions of the bump electrodes LD may correspond to positions of the display pads SD. Thus, bonding reliability between the display panel DP and the circuit board CB may be improved.

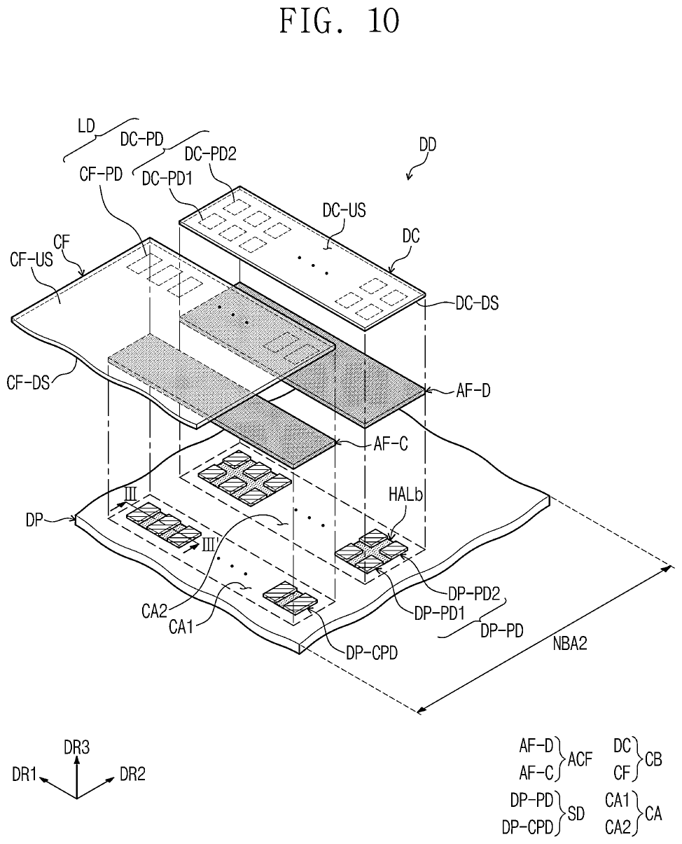

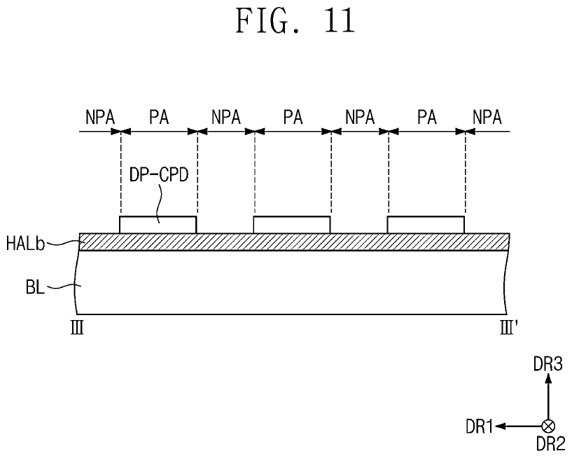

FIG. 10 is a view for describing another embodiment of the disclosure. FIG. 11 is a view for describing another embodiment of the disclosure.

FIG. 10 is a perspective view of an embodiment, and FIG. 11 is a cross-sectional view along line III-III′ illustrated in FIG. 10.

FIG. 10 is a view illustrating an embodiment of a partial area of the second non-bending area NBA2.

FIG. 10 is a schematic view illustrating an embodiment of some components arranged to correspond to the second non-bending area NBA2.

Since the circuit board CB, the conductive adhesive member ACF, and the display pads SD of FIG. 10 are the same as the circuit board CB, the conductive adhesive member ACF, and the display pads SD of FIG. 6, a description thereof will be omitted or simplified.

Since the base layer BL, the second pads DP-CPD, the pad areas PA, and the non-pad areas NPA of FIG. 11 are the same as the base layer BL, the second pads DP-CPD, the pad areas PA, and the non-pad areas NPA of FIG. 7, a description thereof will be omitted or simplified.

Referring to FIGS. 10 and 11, in a plan view, a heat absorbing layer HALb may be disposed in the connection area CA. The heat absorbing layer HALb may be exposed to the outside from an upper surface of the display panel DP.

As illustrated in FIG. 11, the heat absorbing layer HALb may be disposed on the base layer BL. The heat absorbing layer HALb may overlap the pad areas PA and the non-pad areas NPA.

The heat absorbing layer HALb may be an inorganic layer. In an embodiment, the heat absorbing layer HALb may include an antimony tin oxide (“ATO”), but the disclosure is not limited thereto, and the heat absorbing layer HALb may include other inorganic materials that may absorb the near-infrared laser beam.

The display pads SD may be arranged on an upper surface of the heat absorbing layer HALb. The display pads SD may be directly arranged on the upper surface of the heat absorbing layer HALb.

Unlike FIG. 7, since the heat absorbing layer HALb includes an inorganic material, even when the second pads DP-CPD are directly arranged on the heat absorbing layer HALb, the second pads DP-CPD may not be shorted to each other. Thus, the insulating layer IL (refer to FIG. 7) may not be disposed on the heat absorbing layer HALb.

The near-infrared laser beam irradiated from the lower side of the base layer BL in the third direction DR3 may be absorbed by the heat absorbing layer HALb. The heat absorbing layer HALb that absorbs the near-infrared laser beam may emit the heat toward the conductive adhesive member ACF disposed between the display panel DP and the circuit board CB. Accordingly, the conductive adhesive member ACF may be cured to bond the display panel DP and the circuit board CB.

Further, since the near-infrared laser beam is absorbed by the heat absorbing layer HALb, the circuit board CB may not be converted into a high-temperature state due to the absorption of the near-infrared laser beam. Accordingly, the circuit board CB may not be expanded by the heat, and an arrangement of the bump electrodes LD of the circuit board CB may correspond to an arrangement of the display pads SD. Thus, bonding reliability between the display panel DP and the circuit board CB may be improved.

According to an embodiment of the disclosure, a heat absorbing layer having a higher heat absorption rate than that of a circuit board may be disposed between a base substrate and pads. Accordingly, when a lower surface of the base substrate is irradiated with a near-infrared laser beam, the heat absorbing layer may absorb the near-infrared laser beam to emit heat, and the emitted heat may be transferred to a conductive adhesive member disposed between the pads and the circuit board. In this case, since the near-infrared laser beam is absorbed by the heat absorbing layer, the circuit board may be maintained at a lower temperature than that of the heat absorbing layer, and the circuit board may not be expanded due to the heat. Thus, bonding reliability between the display panel and the circuit board may be improved.

Although an embodiment has been described above, those skilled in the art may understand that the disclosure may be variously modified and changed without departing from the spirit and scope of the disclosure described in the appended claims. Further, it should be interpreted that an embodiment disclosed in the disclosure is not intended to limit the technical spirit of the disclosure and all technical spirits within the appended claims and equivalents thereto are included in the scope of the disclosure.

What is claimed is:

1. A display device comprising:
a display panel including:
a base layer;
a plurality of pads arranged on the base layer and spaced apart from each other in a first direction; and
a heat absorbing layer disposed between the base layer and the plurality of pads and overlapping the plurality of pads in a plan view;
a circuit board disposed on the display panel and including a plurality of bump electrodes; and
a conductive adhesive member which electrically connects the display panel and the circuit board.

2. The display device of claim 1, wherein the heat absorbing layer overlaps an area between the plurality of pads spaced apart from each other in the first direction in the plan view.

3. The display device of claim 2, further comprising:
an insulating layer disposed between the heat absorbing layer and the plurality of pads, and
wherein the heat absorbing layer includes metal.

4. The display device of claim 2, wherein the heat absorbing layer includes at least one of titanium, molybdenum, or nickel.

5. The display device of claim 3, wherein the insulating layer covers the heat absorbing layer, and the heat absorbing layer and the plurality of pads are insulated from each other.

6. The display device of claim 3, wherein the insulating layer includes:
a first insulating layer disposed on the base layer; and
a second insulating layer disposed between the first insulating layer and the plurality of pads.

7. The display device of claim 6, wherein the heat absorbing layer includes:
a plurality of first heat absorbing layers arranged on the base layer and covered by the first insulating layer; and
a plurality of second heat absorbing layers arranged on the first insulating layer and covered by the second insulating layer, and
the plurality of first heat absorbing layers overlaps an area between the plurality of pads adjacent to each other in the first direction, and the plurality of second heat absorbing layers overlap the plurality of pads, in the plan view.

8. The display device of claim 7, wherein the plurality of first heat absorbing layers and the plurality of second heat absorbing layers are arranged in different layers.

9. The display device of claim 7, wherein edges of the plurality of first heat absorbing layers overlap edges of the plurality of pads in the plan view.

10. The display device of claim 2, wherein the heat absorbing layer includes an inorganic material.

11. The display device of claim 2, wherein the plurality of pads is arranged on an upper surface of the heat absorbing layer.

12. The display device of claim 2, wherein the heat absorbing layer extends in the first direction in the plan view.

13. The display device of claim 12, wherein an extension direction of the heat absorbing layer and an extension direction of the plurality of pads intersect each other in the plan view.

14. A display device comprising:
a display panel including:
a plurality of pad areas and a plurality of non-pad areas arranged alternately with the plurality of pad areas in a first direction; and
a heat absorbing layer overlapping the plurality of pad areas and the plurality of non-pad areas;
a circuit board disposed on the display panel and including a plurality of bump electrodes; and
a conductive adhesive member which electrically connects the display panel and the circuit board.

15. The display device of claim 14, wherein the display panel includes:
a base layer disposed under the heat absorbing layer; and
a plurality of pads arranged on the heat absorbing layer and overlapping the plurality of pad areas, and
the heat absorbing layer is disposed between the base layer and the plurality of pads.

16. The display device of claim 15, wherein the display panel further includes an insulating layer disposed between the heat absorbing layer and the plurality of pads, and
the insulating layer covers the heat absorbing layer, and the heat absorbing layer includes metal.

17. The display device of claim 16, wherein the metal includes any one of molybdenum, titanium, or nickel.

18. The display device of claim 16, wherein the insulating layer includes:
a first insulating layer disposed on the base layer; and
a second insulating layer disposed between the first insulating layer and the plurality of pads.

19. The display device of claim 18, wherein the heat absorbing layer includes:
a plurality of first heat absorbing layers overlapping the plurality of pad areas; and
a plurality of second heat absorbing layers overlapping the plurality of non-pad areas, and
the first insulating layer covers the plurality of first heat absorbing layers, and the second insulating layer covers the plurality of second heat absorbing layers.

20. The display device of claim 14, wherein the heat absorbing layer includes an inorganic material, and the plurality of pads is arranged on an upper surface of the heat absorbing layer.
